(19) United States
(12) Patent Application Publication
(10) Pub. No.: US 2010/0101845 A1
(43) Pub. Date: Apr. 29, 2010

(54) Electronic Device and Manufacturing Method for Electronic Device

(76) Inventors: Arata Kishi, Osaka (JP); Naomichi Ohashi, Hyogo (JP); Atsushi Yamaguchi, Osaka (JP); Seiji Tokii, Shizuoka (JP); Masato Udaka, Hyogo (JP)

Correspondence Address: WENDEROTH, LIND & PONACK L.L.P., 1030 15th Street, N.W., Suite 400 East, Washington, DC, 20005-1503, US

(21) Appl. No.: 12/605,750

(22) Filed: Oct. 26, 2009

(30) Foreign Application Priority Data
Oct. 27, 2008 (JP) 2008-275108
Feb. 10, 2009 (JP) 2009-028818

(51) Int. Cl. H05K 1/02; B23K 31/02

(52) U.S. Cl. 174/259; 228/224

(57) ABSTRACT

An electronic device manufacturing method includes: setting a solder material on electrodes of a first circuit assembly; setting a resin having a flux action on one surface of a second circuit assembly so as to entirely cover solder bumps formed on the one surface of the second circuit assembly; setting the second circuit assembly on the first circuit assembly via the resin so that the solder material set on the electrodes of the first circuit assembly and the solder bumps of the second circuit assembly are put into contact with each other; and applying thermal energy to connecting portions between the solder material and the solder bumps and to the resin. By carrying out these processes, an electronic device in which the first circuit assembly and the second circuit assembly are joined together and in which their junction portions are sealed by the resin is manufactured. As a result, in the electronic device, junction reliability can be improved.

### BACKGROUND OF THE INVENTION

1. Field of the Invention

The present invention relates to an electronic device, as well as a manufacturing method for the electronic device, which is a multilayered structure of circuit assemblies that are electrically connected to one another via solder bumps. In particular, the invention relates to an electronic device, and a manufacturing method for the electronic device, having a BGA (Ball Grid Array) structure as an array structure of solder bumps.

2. Description of Related Art

For soldering of electronic components onto electronic circuit boards, flux is commonly used. A primary function of the flux is to remove oxide coating films on electrode portions provided in an electronic circuit board as an example of the circuit assembly as well as on electrode surfaces (solder or bump) positioned on surfaces of electronic components also as an example of the circuit assembly to thereby improve the wettability of solder. The flux is not involved in bonding and junction of soldered electronic components after the soldering process. Solder junctions are achieved by melting junction of solder metals. Therefore, bonding strength between soldered metals depends on the area of a solder junction.

In this connection, in various types of electrical equipment, the more the high-density mounting is advanced, the more the electronic components are downsized and the more the array intervals of the electronic components are narrowed. Along with this, the solder junction area is going increasingly narrower and smaller. At the present stage, it is already difficult to secure enough soldering strength. Still, there is a tendency of further advancement toward higher-density mounting, smaller-size electronic components and narrower pitches of electronic component array. With conventional means in which solder junction strength is secured only by solder junction area, it is becoming increasingly difficult to meet this technical trend.

Generally, adopted as a means for securing the solder junction strength is a means that fillet portions are formed on side faces of electronic components with solder to enlarge the solder junction area between electrodes of the electronic components and electrodes of the electronic circuit board electronic. However, since high-density mounting involves lessened junction area of the fillet portions, there is a difficulty adopting a means for increasing the junction strength by the fillet portions.

Under these circumstances, there have been developed soldering fluxes, soldering pastes, and soldering methods capable of providing enough bonding strength for higher-density mounting, smaller-size electronic components and narrower pitches of array intervals of electronic component array.

FIGS. 3(a) to (d) are views showing a mounting method described PTL 1 (JP 2589239 B2) and PTL2 (JP 2001-170798 A), in which mounting methods using resin 3 having a flux action are described.

In this mounting method, the resin 3 having a flux action is applied onto an electronic circuit board 7 having electrodes 8 shown in FIG. 3(a) by dispensing, screen printing or other like means, so that the electrodes are covered with the resin 3 having the flux action as shown in FIG. 3(b). The resin 3 having the flux action is preparatorily prescribed so as to contain a flux agent and a hardening agent. Thereafter, as shown in FIG. 3(c), a bump-added electronic component, i.e. BGA 11, which is a ball grid array, is mounted thereon. Then, the BGA 11 is subjected to a reflow furnace, so that hardening of the resin 3 having the flux action is started as a junction of solder bumps 12 of the BGA 11 and the electrodes 8 of the electronic circuit board 7, and finally the junction is completed as shown in FIG. 3(d). That is, an electronic device is manufactured. In an electronic device manufactured in this way, the resin 3 having the flux action filled into clearances between the BGA 11 and the electronic circuit board 7 contains an adhesive resin and a hardening agent so as to have a function of sealing as an adhesive bonding agent.

### SUMMARY OF THE INVENTION

The mounting method for electronic components (BGA 11) shown in FIGS. 3(a) to (d) adopts a method that the resin 3 having the flux action is applied to the electrodes 8 of the electronic circuit board 7 before mounting of the electronic component (BGA 11). In this method, after the resin 3 having the flux action against the electronic circuit board 7 is applied onto the electronic circuit board 7 having the electrodes 8 by dispensing, screen printing or other like means, an electronic component (BGA 11) is mounted thereon and thermal energy is applied thereto, by which the junction and sealing of the electronic circuit board and the electronic component are completed.

However, this method has such issues as shown below due to the resin 3 having the flux action.

(1) With a larger amount of the resin 3 having the flux action, the resin 3 having the flux action expands to neighboring regions during application of the resin or after the reflow (heat treatment).

Also, with a larger amount of the resin 3 having the flux action, in some cases, the electronic component (BGA 11) may float due to the resin so as to be unconnectable during the heat treatment.

(2) With a smaller amount of the resin 3 having the flux action, the flux action does not work, so that the oxide film on bump electrode surfaces of the electronic component cannot be removed. In this case, reinforcement of solder junctions can only partly be fulfilled, making it necessary to inject a thermosetting adhesive, i.e. so-called underfill, to between the electronic circuit board 7 and the electronic-component BGA 11, hence a need of an additional process.

(3) There is a problem that foams enter into the resin 3 having the flux action. That is, referring to FIG. 3(c), when the electronic component (BGA 11) is joined to the resin 3 having the flux action, foams are left at depression and protrusions of a lower surface of the electronic component (BGA 11), causing connections to be unstable during heat treatment or after the junction.

In another aspect of electronic devices, along with the trend toward lighter, thinner, shorter and smaller configurations of electronic equipment, there has been a growing demand for downsizing and thinning of packages for electronic devices that constitute such electronic equipment. In response to such a demand, mounting methods using bare-state semiconductor chips (hereinafter, referred to merely as chips) have been being advanced. As such mounting methods, typically known are COB (Chip On Board) mounting method, flip chip mounting method and the like.

The flip chip mounting method is a method in which metal bump electrodes (hereinafter, referred to merely as bumps) made of solder or the like and provided on a device formation surface of a chip are pressed to land pads of interconnect patterns or the like formed on a circuit board as a motherboard so that their connections are achieved. With this method, higher-density mounting than with the COB mounting that requires wire bonding can be achieved. However, because the coefficient of thermal expansion of the circuit board is larger than that of the chips, stress is applied to the connection portions in the board or chips by thermal expansion of the board, the stress-applied portions may be damaged so that the connection reliability is damaged, as an issue.

As a structure for improving this and other issues, there has been provided a single-sided resin sealed package in which resin is interposed between a circuit board of the multilayer interconnection structure and a chip so that the circuit board and the chip are mechanically fixed. One example of the single-sided resin sealed package is the BGA type package structure. This structure has an advantage that stress at the connecting portions between a circuit board, which is one of the package component elements, and chips can be reduced. On the other hand, there arises thermal stress due to differences in thermal expansion coefficient between chips and the circuit board that hold the chips thereon, causing occurrence of a phenomenon that the circuit board is warped. As a result of this, coplanarity of the circuit board degrades, making it hard to mount electronic devices of the BGA package type onto the motherboard.

Thus, in order to suppress such coplanarity degradation to the utmost, there has been proposed a method in which grooves are provided on a chip-mount surface side of the circuit board so as to adjoin an outer end of the chip while avoiding interconnect patterns and the like, and moreover in which a mold releasing agent is applied onto surfaces of the grooves to impart peelability to the resin filled between the circuit board and the chips mounted thereon (see, e.g., PTL 3: JP H10-233463 A).

While the demand for downsizing and thinning of packages for electronic devices has been becoming increasingly stronger, chips are under further advancement toward higher capacity and higher density along with improvement of their performance and functions, there is also a desire for a package structure that allows the chips to be mounted at even higher densities on the circuit board.

As a mounting structure to meet such a demand, there is a proposal as follows (see, e.g., PTL 4: JP 2008-510304 A). That is, a circuit board in which interconnect patterns and interconnect terminals connected thereto are provided on one surface of the board while a land pad is provided on the other surface is used. The interconnect terminal is so formed as to be higher than a position of a top face of the chip mounted on the circuit board. Then, the chip is mounted on the interconnect-pattern formation surface side, and the chip is sealed with resin so that a top face of the interconnect terminal is exposed, by which a sub package is made up. Such a sub package is prepared in plurality and stacked one on another so that the interconnect terminal of one sub package is connected to the land pad of the other sub package. It is also allowable to use a sub package in which chips are multilayered in stack as required.

With the former method, in which grooves are provided on a chip-mount surface side of the circuit board and the mold releasing agent is applied onto the surface, it is expected that coplanarity degradation of the circuit board in mounting of chips can be improved.

However, with this method, after the connection of the interconnect patterns and the chip bumps, it is required to fill the sealing resin to between the chips and the interconnect patterns and moreover cover peripheral portions of the chips and the interconnect patterns with resin. For the connection of the interconnect patterns and the bumps, it is required to remove oxide film formed on surfaces in regions serving as their connecting places, and flux is widely used for this purpose. Use of flux inevitably causes the flux to be partly left between the chip and the circuit board. To fulfill embedment of the resin, which has been used for sealing, to between the chips and the interconnect patterns without clearances, it is necessary to remove, in advance, the residues of the flux present between the chips and the interconnect patterns. This removal process is a factor of cost increases of electronic devices.

Further, in each of connection and resin hardening processes, heating process is involved in connection of the chip bumps and the interconnect patterns and in hardening of the sealing resin injected between the chips and the interconnect patterns. Thus, thermal energy has to be given at least two times in mounting process, which is another factor of cost increases of electronic devices.

With the latter method, electroconductive metal balls are used as interconnect terminals for connection of sub packages to each other. If such metal balls serving as connecting terminals vary in diameter among themselves, there is a fear that when succeeding sub packages are mounted and connected by reflow process, there may occur places where the connection between the sub packages is not securely achieved. Besides, for secure connection among a plurality of sub packages via connection between the interconnect terminal of one sub package and the land pad of the other sub package, it is necessary to keep top portions of the metal balls exposure without being embedded in the sealing resin. On the contrary, if connecting portions remain in the exposure state even after the connection, there is a fear that the electronic device may be degraded in reliability. In order to maintain the connection reliability, it is desirable that all the regions of clearances of sub packages, after their stacking, be filled with the resin so as to be sealed including the connecting portions. However, a filling and sealing process is necessitated for that purpose, which is a factor of cost increases of the electronic devices.

Accordingly, an object of the present invention, lying in solving these and other problems, is to provide an electronic device, as well as a manufacturing method therefor, which is a multilayered structure of circuit assemblies that are electrically connected to one another via solder bumps and which is improved in connection reliability.

In order to achieve the above object, the present invention has the following constitutions.

According to a first aspect of the present invention, there is provided an electronic device comprising:

a first circuit assembly having electrodes;

a second circuit assembly which is set opposite to an electrode formation surface of the first circuit assembly and which has solder bumps electrically connected to the electrodes, respectively; and

a resin which is set between the first circuit assembly and the second circuit assembly to join together the first circuit assembly and the second circuit assembly and which seals the electrodes and the solder bumps connected to each other, respectively, wherein

at least two or more kinds of flux components including a flux component for solder bumps are mixed up so as to be dispersed in the resin.

According to a second aspect of the present invention, there is provided the electronic device as defined in the first aspect, wherein the second circuit assembly has electrodes formed on a surface opposed to a bump formation surface of the second circuit assembly, the electronic device further comprising:

a third circuit assembly which is set opposite to an electrode formation surface of the second circuit assembly and which has solder bumps electrically connected to the electrodes, respectively; and

a resin which is set between the second circuit assembly and the third circuit assembly to join together the second circuit assembly and the third circuit assembly and which seals the electrodes and the solder bumps connected to each other, respectively.

According to a third aspect of the present invention, there is provided the electronic device as defined in the first aspect, wherein two or more kinds of organic acids having different melting points are contained as flux components in the resin.

According to a fourth aspect of the present invention, there is provided the electronic device as defined in the third aspect, wherein a melting point range of one flux component contained in the resin and a melting point range of another flux component contained in the resin have a mutually overlapped temperature range.

According to a fifth aspect of the present invention, there is provided the electronic device as defined in the third aspect, wherein as the two or more kinds of organic acids having different melting points, diglycollic acid and glutaric acid are contained in the resin.

According to a sixth aspect of the present invention, there is provided the electronic device as defined in the first aspect, wherein flux components within a quantity range of 1 to 20 wt % are contained and dispersed in the resin.

According to a seventh aspect of the present invention, there is provided an electronic device manufacturing method comprising:

setting a solder material on electrodes of a first circuit assembly;

setting a resin having a flux action on one surface of a second circuit assembly so as to entirely cover solder bumps formed on the one surface of the second circuit assembly;

setting the second circuit assembly on the first circuit assembly via the resin so that the solder material set on the electrodes of the first circuit assembly and the solder bumps of the second circuit assembly are put into contact with each other; and

applying thermal energy to connecting portions between the solder material and the solder bumps and to the resin, whereby

an electronic device in which the first circuit assembly and the second circuit assembly are joined together and in which their junction portions are sealed by the resin is manufactured.

According to an eighth aspect of the present invention, there is provided the electronic device manufacturing method as defined in the seventh aspect, wherein

in the thermal energy applying process, the thermal energy is applied to junction portions and the resin without exerting pressure between the first circuit assembly and the second circuit assembly.

According to a ninth aspect of the present invention, there is provided the electronic device manufacturing method as defined in the seventh aspect, wherein

in the thermal energy applying process, the thermal energy is applied to the resin having the flux action, whereby oxide films on surfaces of the solder bumps are removed so that the solder bumps are electrically connected to the electrodes of the first circuit assembly.

According to a tenth aspect of the present invention, there is provided the electronic device manufacturing method as defined in the seventh aspect, wherein

in the thermal energy applying process, the thermal energy is applied to the resin having the flux action, whereby the resin is hardened.

According to an eleventh aspect of the present invention, there is provided the electronic device manufacturing method as defined in the seventh aspect, wherein

in the process of setting the resin having the flux action on one surface of the second circuit assembly, the one surface of the second circuit assembly is brought into contact with a resin layer formed to a thickness higher larger than a height of the solder bumps, whereby the resin layer is transferred onto the second circuit assembly.

According to a twelfth aspect of the present invention, there is provided the electronic device manufacturing method as defined in the seventh aspect, further comprising:

setting the solder material onto electrodes formed on the other surface of the second circuit assembly;

setting the resin having the flux action onto one surface of a third circuit assembly so as to entirely cover solder bumps formed on the one surface of the second circuit assembly; and

setting the third circuit assembly onto the second circuit assembly via the resin so that the solder material set on the electrodes of the second circuit assembly and the solder bumps of the third circuit assembly are put into contact with each other, whereby

in the thermal energy applying process, the thermal energy is applied to connecting portions of the solder material and the solder bumps between the first circuit assembly, the second circuit assembly and the third circuit assembly, so that the first circuit assembly, the second circuit assembly and the third circuit assembly are joined together and moreover their individual connecting portions are sealed by the resin, whereby an electronic device is manufactured.

According to a 13th aspect of the present invention, there is provided the electronic device manufacturing method as defined in the seventh aspect, wherein the solder bumps formed on the second circuit assembly have a BGA structure.

According to a 14th aspect of the present invention, there is provided the electronic device manufacturing method as defined in the seventh aspect, wherein

in the process of setting the resin having the flux action onto one surface of the second circuit assembly, a resin containing a principal ingredient of a resin material, a hardener of the principal ingredient, and an organic acid having the flux action are set onto the one surface of the second circuit assembly.

According to a 15th aspect of the present invention, there is provided the electronic device manufacturing method as defined in the 14th aspect, wherein at least two or more kinds of organic acids having different melting points are contained as the resin having the flux action.

According to a 16th aspect of the present invention, there is provided the electronic device manufacturing method as defined in the 15th aspect, wherein

the solder material set on the electrodes of the first circuit assembly contains a flux component, and

a softening point range of the flux component of the solder material and a melting point range of the two or more kinds of organic acids contained in the resin has a mutually overlapping temperature range.

According to a 17th aspect of the present invention, there is provided the electronic device manufacturing method as defined in the 15th aspect, wherein as the two or more kinds of organic acids having different melting points, diglycollic acid and glutaric acid are contained in the resin.

According to an 18th aspect of the present invention, there is provided the electronic device manufacturing method as defined in the seventh aspect, wherein flux components within a quantity range of 1 to 20 wt % are contained in the resin.

According to a 19th aspect of the present invention, there is provided an electronic device manufacturing method comprising:

setting a solder material on a board electrode of a circuit board;

setting a resin having a flux action on an electrode of a chip component;

mounting the chip component onto the circuit board via the resin so that the solder material set on the board electrode of the circuit board and the electrode of the chip component are put into contact with each other; and

applying thermal energy to the solder material and the resin, wherein

an electronic device in which the electrode of the chip component is electrically connected to the board electrode of the circuit board via the solder material and in which their connecting portions are sealed by the resin is manufactured.

According to the present invention, after the resin having the flux action is set on the second circuit assembly so as to entirely cover solder bumps formed of the second circuit assembly, the first circuit assembly having the solder material set on its electrodes and the second circuit assembly are layer-stacked, and thermal energy is applied to the stacked structure, by which its electrical junction by melting and hardening of the solder and the resin sealing of the connecting portions by the hardening of the resin can be achieved concurrently in one-time process. Also, since the solder bumps are entirely covered with the resin having the flux action, oxide films all over surfaces of the solder bumps can be removed by the application of thermal energy, so that electroconductivity of the junction between the solder material and the solder bumps can be secured stably. Also, after the resin is preparatorily set on the second circuit assembly, the first circuit assembly and the second circuit assembly are layer-stacked, so that mixing of voids or the like is less likely to occur during the junction process. Further, in the second circuit assembly, since the resin set so as to entirely cover the solder bumps has the flux action, occurrence of residues as would occur when the flux alone is used for the connecting portions between the solder bumps and the solder material can be blocked. Accordingly, in the electronic device in which the first circuit assembly and the second circuit assembly are layer-stacked, stable junction can be realized and junction reliability can be improved.

Furthermore, after the resin having the flux action is set on the third circuit assembly so as to entirely cover solder bumps of the third circuit assembly, the third circuit assembly is stacked and set on the second circuit assembly, where thermal energy is applied collectively to connecting portions and resin of the first circuit assembly, the second circuit assembly and the third circuit assembly. As a result, an electronic device of a multilayered structure in which the first, second and that circuit assemblies are stacked one on another and in which the connecting portions are sealed can be manufactured. Also, the junction reliability in such an electronic device of a multilayered structure can be improved.

### BRIEF DESCRIPTION OF THE DRAWINGS

These aspects and features of the present invention will become clear from the following description taken in conjunction with the preferred embodiments thereof with reference to the accompanying drawings, in which:

FIG. 1 is a view for explaining processes of a mounting method for solder-added electronic components in Example 1 according to a first embodiment of the present invention;

FIG. 2 is a view for explaining processes of a mounting method for bump-added electronic components in Example 2 according to the first embodiment of the invention;

FIG. 3 is a view shown as to a conventional mounting method;

FIG. 4 is a view relating to a mounting method for solder-added electronic components in Comparative Example 1 as a prior art;

FIG. 5 is a view relating to a mounting method for solder-added electronic components in Comparative Example 2 of the conventional method;

FIG. 6 is a view relating to a mounting method for bump-added electronic components in Comparative Example 3 of the conventional method;

FIG. 7 is an enlarged sectional view of a structure fabricated in Comparative Example 3 of the conventional method;

FIG. 8 is an enlarged sectional view of a structure fabricated in Example 2 of the first embodiment;

FIG. 9 is an enlarged sectional view of a structure fabricated in an example of the first embodiment;

FIG. 10 is an enlarged sectional view of a structure fabricated in a conventional structure;

FIG. 11 is a view for explaining processes of a preceding stage in the second embodiment of the invention;

FIG. 12 is a view for explaining processes of a succeeding stage in the second embodiment;

FIG. 13 is a view for explaining main part of processes in Comparative Example 5;

FIG. 14 is an enlarged partial sectional view of an electronic device in the second embodiment;

FIG. 15 is an enlarged partial sectional view of an electronic device in Comparative Example 4;

FIG. 16 is an enlarged partial sectional view of an electronic device in Comparative Example 5;

FIG. 17 is a view for explaining processes in a third embodiment of the invention;

FIG. 18 is a view for explaining main part of processes in Comparative Example 6; and

FIG. 19 is a view showing a result of X-ray transmission examination of electronic devices by the third embodiment and Comparative Example 7.

### DETAILED DESCRIPTION OF THE PREFERRED EMBODIMENTS

Before the description of the present invention proceeds, it is to be noted that like parts are designated by like reference numerals throughout the accompanying drawings.

Hereinbelow, embodiments of the invention will be described in detail with reference to the drawings.

### First Embodiment

An electronic device manufacturing method according to a first embodiment of the invention includes: a process for setting a solder material on board electrodes of a circuit board; a process for setting resin having a flux action on electrodes of a chip component; a process for mounting the chip component onto the circuit board via the resin so that the solder material set on the board electrodes of the circuit board and the electrodes of the chip component are put into contact with each other; and a process for applying thermal energy to the solder material and the resin, whereby the method is to manufacture an electronic device in which the electrodes of the chip component are electrically connected to the board electrodes of the circuit board via the solder material and their connecting portions are sealed by the resin. This electronic device manufacturing method will be explained by taking a concrete example as Example 1 later.

Another electronic device manufacturing method according to the first embodiment includes: a process for setting a solder material on electrodes of a first circuit assembly; a process for setting resin having a flux action on one surface of a second circuit assembly so that an entirety of a solder bump formed on the one surface of the second circuit assembly is covered with the resin; a process for setting the second circuit assembly on the first circuit assembly via the resin so that the solder material set on the electrodes of the first circuit assembly and the solder bump of the second circuit assembly are put into contact with each other; and a process for applying thermal energy to connecting portions of the solder material and the solder bump as well as to the resin, whereby the method is to manufacture an electronic device in which the first circuit assembly and the second circuit assembly are joined together and their junction portions are sealed by the resin. This electronic device manufacturing method will be explained by taking a concrete example as Example 2 later.

Here are described concepts in common among these electronic device manufacturing methods.

Herein, the term ‘circuit assembly’ refers to a structure in which electronic circuits are formed, including electronic circuit boards with circuit patterns formed thereon, IC components or other electronic components, and the like.

The process for setting resin having a flux action on electrodes of a chip component, and the process for setting resin having a flux action on one surface of a second circuit assembly so that an entirety of a solder bump formed on the one surface of the second circuit assembly is covered with the resin, are each a process for setting a chip component or a second circuit assembly on a resin layer having a flux action formed to a certain thickness, and transferring a necessary amount of the resin having the flux action.

The process for setting a solder material on board electrodes of a circuit board, and the process for setting a solder material on electrodes of a first circuit assembly, are intended to fulfill setting of the solder material by using a solder paste printing machine or dispenser for surface mount in common use or the like. The solder material to be used is a commercially available paste-state one (cream-like one) composed of Sn-3Ag-0.5Cu or Sn-42Bi or the like.

The process for mounting the chip component onto the circuit board via the resin so that the solder material set on the board electrodes of the circuit board and the electrodes of the chip component are put into contact with each other, and the process for setting the second circuit assembly on the first circuit assembly via the resin so that the solder material set on the electrodes of the first circuit assembly and the solder bump of the second circuit assembly are put into contact with each other, are carried out by using a mounter or electronic component mounting machine for surface mount in common use.

The process for applying thermal energy to the solder material and the resin, and the process for applying thermal energy to connecting portions of the solder material and the solder bump as well as to the resin, are carried out by using a reflow furnace for surface mount in common use. That is, the circuit board with chip components mounted thereon or the multilayered circuit assemblies are heated within the reflow furnace while the chip and the circuit board or the circuit assemblies are not under pressure (i.e., without any external force applied).

The resin having the flux action may be provided in a liquid or paste form. A resin material to be used as a principal agent of the resin is preferably a thermosetting resin. Specific examples of the resin material include at least one kind of epoxy resin, phenol resin, polyimide resin, silicone resin as well as their modified resins and acrylic resin. Kind and blending quantity of the resin material to be used may be selected depending on bonding temperature zone, target coating film hardness and the like. A hardening agent therefor may be any one that allows the resin material in use to be hardened.

Components for developing the flux action may be an organic acid that produces reduction action, as well as a carboxylic acid or the like. Such flux components have an action of removing metal oxide coating films formed on the solder bumps, the interconnect patterns and the like. The content rate of the flux is preferably 1-20 wt % for the resin having the flux action.

Less than 1 wt % content ratios of the flux would cause the substantial flux action to be nullified. Therefore, in a case where the electronic component is a chip component as an example, it is impossible to sufficiently remove oxide coating films of plating by the flux action. Also, when the electronic component has solder balls of the BGA structure, oxide coating films of the solder balls cannot be sufficiently removed, resulting in junction in an insufficient state of sinking of the solder balls by fusion (i.e., a state of insufficient configurational change of the solder balls by melting), which leads to impossibility of stable junction. Meanwhile, 20 wt % or more content ratios of the flux in the resin would make it impossible to obtain target hardened material properties (hardness or insulation resistance of the resin). In such a case, specifications of the resin become poorer in terms of heat cycle tests or drop tests, as compared with conventional underfill agents used for structures of this type.

The resin having the flux action may contain a solvent, a plasticizer, a thixotropic agent or the like. The solvent, the plasticizer and the thixotropic agent are added to adjust the viscosity depending on the coating application form. The blending ratios of the solvent, the plasticizer, the thixotropic agent or the like may be set to those suited to the purpose of use.

### Example 1

An example in which an electronic component (chip component) with no solder bumps added thereon such as resistors or other electronic components is mounted on an electronic circuit board via solder material will now be explained with reference to the accompanying drawings.

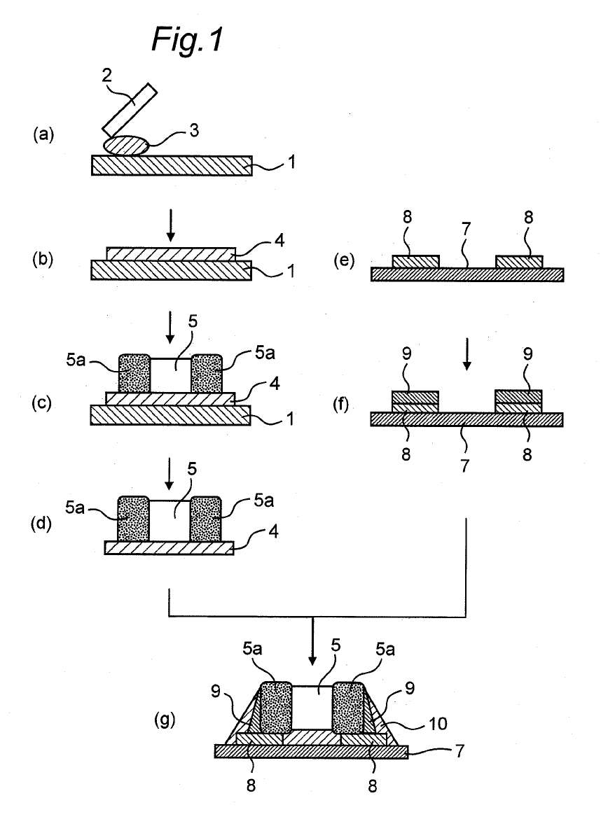

FIG. 1 is a view relating to a mounting method for a chip component 5, which is an electronic component, in Example 1 of the invention.

A resin 3 having the flux action was thrown onto a material pot 1 (FIG. 1(a)). Next, with use of a squeegee 2, a layer of a resin 4 having the flux action and having a certain film thickness was formed (FIG. 1(b)). Next, for transfer of the resin 3 having the flux action, the chip component 5 was mounted on the layer of the resin 4 having the flux action and having a certain film thickness (FIG. 1(c)). By pull-up of the mounted chip component 5, a chip component 5 onto which a necessary amount of the resin 3 (i.e., resin layer) having the flux action had been transferred was obtained (FIG. 1(d)). In more detail, the resin 3 is transferred to an entirety of a lower surface of the chip component 5 as viewed in the figure so that the resin 3 is set onto lower surfaces of individual electrodes 5a of the chip component 5 as viewed in the figure.

Also, an electronic circuit board 7 was prepared (FIG. 1(e)). On the electrodes 8 (board electrodes) of the electronic circuit board 7, solder paste 9 (solder material) of Sn-3Ag-0.5Cu was printed thereon by a screen printing machine (FIG. 1(f)).

Next, the chip component 5 onto which the resin 4 having the flux action and having a certain film thickness had been transferred was mounted on the electronic circuit board 7 on which the solder paste 9 of Sn-3Ag-0.5Cu had been printed, and then the solder paste 9 and the electrodes 5a of the chip component 5 were put into contact with each other. In a state that the chip component 5 was mounted on the electronic circuit board 7 via the resin 4, reflow process is performed. By the reflow operation, thermal energy was imparted to the resin 4 and the solder paste 9 so that the solder paste 9 was melted and thereafter solidified while the resin 4 was hardened, by which a mount structure (electronic device) was obtained (FIG. 1(g)).

By this method, a structure was able to be obtained in which enough junction area between the chip component 5 and the electronic circuit board 7 was secured by the solder paste 9 of Sn-3Ag-0.5Cu printed on the electrode portions of the electronic circuit board, with the junction area peripherally covered with the flux resin. Also by this method, since enough junction area was able to be obtained by the formation of fillets 10 on side faces of the chip component 5, which is an electronic component, a stable connection resistance was able to be obtained.

The resin 3 having the flux action used in the above description has the following composition and physical properties. A ratio of 15 wt % of an imidazole hardener (2P4MZ) (made by Shikoku Chemicals Corporation) and 15 wt % of adipic acid (made by Kanto Chemical Industry Co., Ltd.) as a carboxylic acid showing the reduction action were kneaded with 70 wt % of bisphenol A-type epoxy resin (made by Japan Epoxy Resins Co., Ltd.) by a mortar grinder, by which a resin having the flux action and showing a viscosity of 69 Pa·s (1 rpm) by E-type viscometer was fabricated and used.

The film thickness of the flux resin in FIG. 1(b) was set to 100 μm.

Also, printing of the solder paste 9 was done by using a 100 μm thick mask.

As the electronic component (chip component 5), 1608 chips made by Panasonic Electronic Devices Co., Ltd. were used. As the electronic circuit board 7, one having preflux-treated copper interconnect lines was used.

These constituent members are each one example only, and not limitative.

### Comparative Example 1

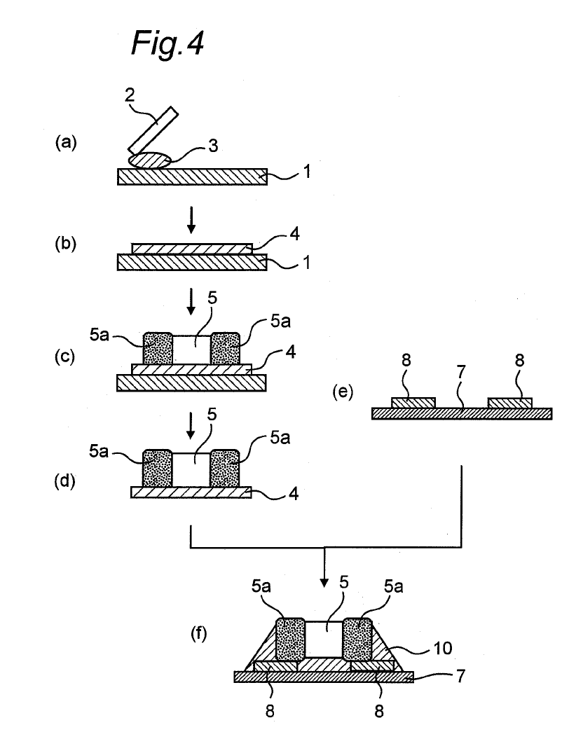

For comparison's sake, a mount structure (electronic device) was fabricated by a mounting method described below. The mounting method for comparison is a mounting method in which the process for printing the solder paste 9 on the electrodes 8 of the electronic circuit board 7 is excluded from the mounting method of Example 1. Comparative Example 1 is explained below with reference to the accompanying drawings. FIGS. 4(a) to 4(f) are views relating to a mounting method for a solder-added electronic component in Example 1. For constituent members common to Example 1, the same constituent members were used.

A resin 3 having the flux action was thrown onto a material pot 1 (FIG. 4(a)). Next, with use of a squeegee 2, a layer of a resin 4 having the flux action and having a certain film thickness was formed (FIG. 4(b)). Next, for transfer of the resin 3 having the flux action, the chip component 5 was mounted on the layer of the resin 4 having the flux action and having a certain film thickness (FIG. 4(c)). By pull-up of the mounted chip component 5, a chip component 5 onto which a necessary amount of the resin 3 having the flux action had been transferred was obtained (FIG. 4(d)). Subsequently, an electronic circuit board 7 with no solder paste of Sn-3Ag-0.5Cu printed thereon was prepared (FIG. 4(e)). The chip component 5 onto which a necessary amount of the resin 3 having the flux action had been transferred was mounted on the electronic circuit board 7 with no solder paste of Sn-3Ag-0.5Cu printed thereon, and then passed through reflow, by which a mount structure was obtained (FIG. 4(f)).

The individual conditions in this case are the same as in Example 1.

### Comparative Example 2

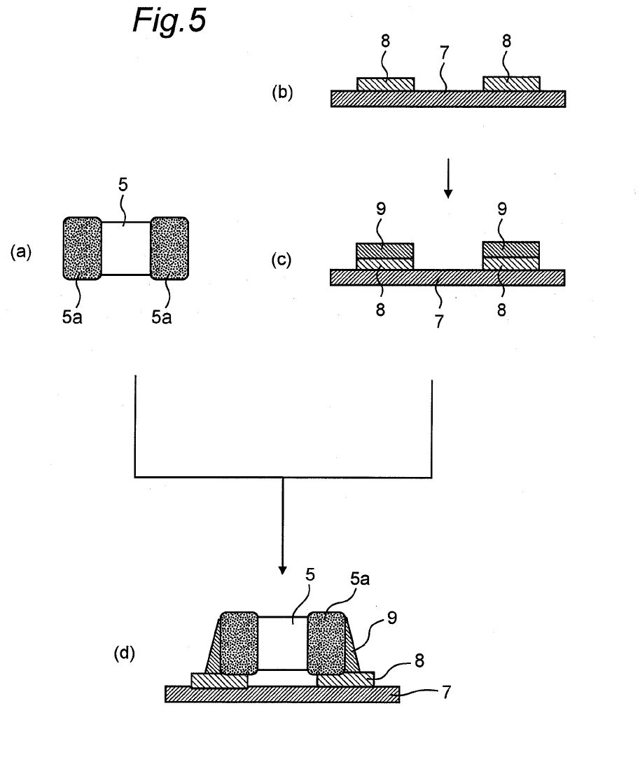

For comparison's sake, a mount structure (electronic device) was fabricated by a mounting method described below. The mounting method for comparison is a mounting method in which the process for applying the resin 3 having the flux action to solder surfaces is excluded from the mounting method of Example 1. Comparative Example 2 is explained below with reference to the accompanying drawings. FIG. 5 is a view relating to the mounting method for solder-added electronic components in Comparative Example 2. For constituent members common to Example 1, the same constituent members were used.

First, an electronic circuit board 7 was prepared (FIG. 5(b)). Next, with use of a screen printing machine, solder paste 9 of Sn-3Ag-0.5Cu was printed on electrodes 8 of the electronic circuit board 7 (FIG. 5(C)). Next, a chip component 5 was prepared (FIG. 5(a)). The chip component was mounted on the electronic circuit board 7 with the solder paste 9 of Sn-3Ag-0.5Cu printed thereon, and then passed through reflow, by which a mount structure was obtained (FIG. 5(d)).

### Test

Table 1 shows connection resistance values of each ten mount structures fabricated by Example 1 and Comparative Examples 1 and 2. In comparison to Example 1, Comparative Example 1 showed a result that not enough junction area was able to be secured between the chip component 5 and the electronic circuit board 7, with resistance values higher than those with solder printed such that the junction was impossible in some cases. In consequence, it proved apparent that Comparative Example 1 is incapable of obtaining stable connection resistance, unlike Example 1.

From this result, it can be seen that in the case where an electronic component obtained by printing solder on board electrodes of the electronic circuit board and thereafter setting resin having the flux action onto the electrodes is mounted on the electronic circuit board with solder printed on its board electrodes, stable connection resistance can be obtained so that junction reliability can be improved.

Also, in comparison between Example 1 and Comparative Example 2, it proved apparent that fillets 10 containing metal junction of solder can be formed by printing solder on electrode portions of the electronic circuit board, and that connection resistance values equivalent to those of solder junctions can be obtained. It was easily achievable to form fillets by metal junction of solder as well as formation of a mount structure with its peripheries covered with the resin. That is, the fillets 10 of Comparative Example 1 is made of a solder component only, whereas the fillets 10 of Example 1 are made of both solder and resin components so as to be superior in strength to Comparative Example 2 and moreover generally equivalent in resistance value to Comparative Example 2 with certainty.

TABLE 1

| | | Comparative | Comparative |
|---|---|---|---|
| | Example 1 | Example 1 | Example 2 |
| Sample No. | Resistance value (mΩ) | | |
| 1 | 13.2 | Unmeasurable | 11.9 |
| 2 | 13.3 | 17.7 | 11.7 |
| 3 | 14.3 | Unmeasurable | 11.5 |
| 4 | 13.2 | 18.6 | 11.8 |
| 5 | 13.7 | 17.0 | 12.2 |
| 6 | 13.4 | 18.7 | 12.2 |
| 7 | 13.3 | 17.1 | 11.6 |
| 8 | 12.8 | Unmeasurable | 12.0 |
| 9 | 14.9 | Unmeasurable | 12.1 |
| 10 | 13.7 | Unmeasurable | 12.0 |
| Ave. | 13.6 | 17.8 | 11.9 |
| Min. | 12.8 | 17.0 | 11.5 |
| Max. | 14.9 | 18.7 | 12.2 |

### Example 2

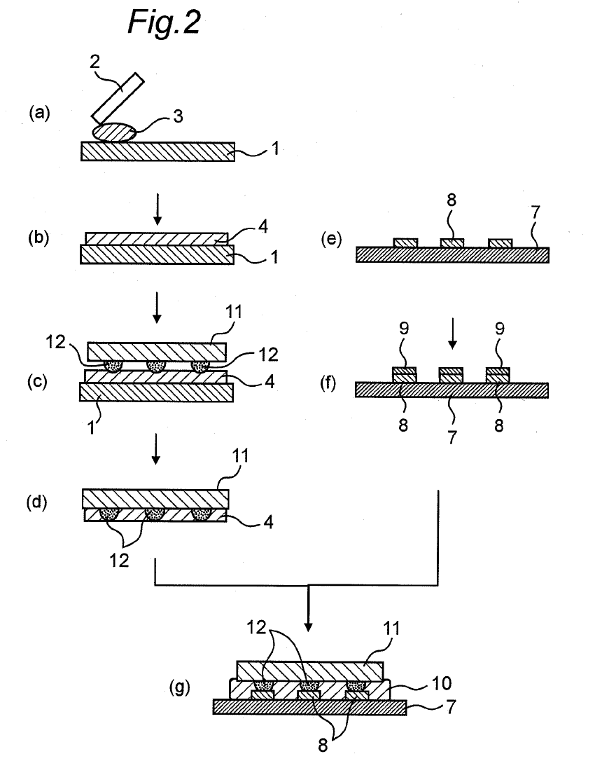

As Example 2 of the invention, a method in which a bump-added electronic component as an example of the second circuit assembly is mounted on an electronic circuit board as an example of the first circuit assembly will now be explained below with reference to the accompanying drawings. FIGS. 2(a) to 2(g) are views relating to the mounting method for bump-added electronic components in Example 2 of the invention.

A resin 3 having the flux action was thrown onto a material pot 1 (FIG. 2(a)). Next, with use of a squeegee 2, a layer of a resin 4 having the flux action and having a certain film thickness was formed (FIG. 2(b)). Next, for transfer of the resin 3 having the flux action, a bump-added electronic component (BGA 11) was mounted on the layer of the resin 4 having the flux action and having a certain film thickness (FIG. 2(c)). By pull-up of the mounted bump-added electronic component, a bump-added electronic component (BGA 11) onto which the resin 4 having the flux action and having a certain film thickness had been transferred was obtained (FIG. 2(d)). In this case, the resin 4 is transferred to a lower surface of the electronic component 11 as viewed in the figure so as to cover an entirety of each bump 12 (e.g., solder bump) formed on the lower surface of the electronic component 11 as viewed in the figure.

Also, an electronic circuit board 7 was prepared (FIG. 2(e)). On the electrodes 8 (board electrodes) of the electronic circuit board 7, solder paste 9 of Sn-3Ag-0.5Cu was printed by a screen printing machine (FIG. 2(f)).

Next, the bump-added electronic component (BGA 11) onto which the resin 4 having the flux action and having a certain film thickness had been transferred was mounted on the electronic circuit board 7 on which the solder paste of Sn-3Ag-0.5Cu had been printed, so that the bumps 12 of the electronic component 11 were put into contact with the solder paste 9 of the electronic circuit board 7. Reflow operation is done in this state, by which thermal energy was imparted to the bumps 12, the solder paste 9 and the resin 4 so that the solder bumps 12 and the solder paste 9 were melted and thereafter solidified while the resin 4 was hardened, by which a mount structure (electronic device) was obtained (FIG. 2(g)).

By this method, a structure was able to be obtained in which enough junction area between the bump-added electronic component (BGA 11) and the electronic circuit board 7 was secured by the solder paste 9 printed on the electrode 8 of the electronic circuit board 7, with the junction area peripherally covered with the fillets 10 of the flux resin.

In the case of the bump-added electronic component (BGA 11), there are some cases where connection failures may occur due to clearances between the bumps 12 and the electrodes 8 of the electronic circuit board that are caused by variations in size of the solder balls used for the bumps 12 as well as warp of the electronic circuit board 7. However, in this embodiment, non-junction was able to be prevented by introducing the process for printing the solder paste 9 of Sn-3Ag-0.5Cu on the electrodes 8 of the electronic circuit board 7.

Also by this mounting method, since enough resin 4 having the flux action to seal between the electronic component (BGA 11) and the electronic circuit board 7 can be supplied onto the surfaces of the bumps 12 of the electronic component in the process for applying the resin 3 having the flux action, it becomes possible to eliminate voids 15 between the electronic component and the electronic circuit board.

The resin 3 having the flux action used in this case has the following composition and physical properties. A ratio of 15 wt % of an imidazole hardener (2P4MZ) (made by Shikoku Chemicals Corporation) and 15 wt % of adipic acid (made by Kanto Chemical Industry Co., Ltd.) as a carboxylic acid showing the reduction action were kneaded with 70 wt % of bisphenol A-type epoxy resin (made by Japan Epoxy Resins Co., Ltd.) by a mortar grinder, by which a resin having the flux action and showing a viscosity of 69 Pa·s (1 rpm) by E-type viscometer was obtained.

The film thickness of the flux resin in FIG. 2(b) was set to 150 μm. A thickness of the bumps 12 was considered in addition to the film thickness of the flux resin of FIG. 1(b). Such a film thickness of the flux resin is preferably set to a film thickness that allows each bump 12 to be entirely covered, i.e., that blocks the bumps 12 from being exposed from the resin 4 having the flux action. More preferably, the film thickness of the flux resin is set to, for example, within a range of 100% to 110% of the height of the bump 12. It is also allowable to, after transfer of flux resin having a larger film thickness, reshape the resin to a proper film thickness by means of a squeegee or the like.

Also, printing of the solder paste was done by using a 120 μm thick mask.

As the electronic component (BGA 11), BGA packages (package size: 8.0 mm, ball diameter: 0.3 mm, ball pitch: 0.5 mm, ball count: 441 pcs.) made by Semiconductor Company, Matsushita Electric Industrial Co., Ltd were used. As the electronic circuit board 7, one having preflux-treated copper interconnect lines was used.

### Comparative Example 3

Comparative Example 3 is aimed at sealing the electronic circuit board and the electronic component with use of an underfill agent. For comparison's sake, a mount structure (electronic device) was fabricated by a mounting method described below. A soldering method for comparison includes: a process for printing solder on electrode portions of an electronic circuit board; a process for mounting an electronic component onto the electronic circuit board with solder printed on electrode portions of the electronic circuit board; a process for applying thermal energy to the bumps of the electronic component and to the electrode portions of the electronic circuit board on which the solder has been printed; a process for applying an underfill agent to clearances between the electronic circuit board and the electronic component; and a process for applying thermal energy to the underfill agent present at the clearances between the electronic circuit board and the electronic component. This method is made up of a commonly practiced mounting method and a subsequent process for inserting sealing-use underfill material, i.e. resin material, to between the circuit board and the electronic component. For constituent members common to Example 2 (i.e., electronic component, bump, electronic circuit board, and solder paste), the same constituent members were used.

The process for applying solder to electrode portions of the electronic circuit board used in Comparative Example 3 is carried out by using a solder paste printing machine or dispenser for surface mount in common use or the like. The solder to be used is a commercially available paste-state one composed of Sn-3Ag-0.5Cu or Sn-42Bi or the like.

The process for mounting an electronic component used in Comparative Example 3 onto the electronic circuit board with solder printed on electrode portions of the electronic circuit board is carried out by using a mounter or mounting machine for surface mount in common use.

The process for applying thermal energy to the bumps of the electronic component used in Comparative Example 3 and to the electrode portions of the electronic circuit board with solder printed thereon is carried out by using a reflow furnace for surface mount in common use.

The underfill agent to be filled into clearances between the electronic component and the electronic circuit board used in Comparative Example 3 is a thermosetting resin in common use. The micro dispenser for applying the underfill agent is a micro dispenser for surface mount in common use.

The process for applying thermal energy to the underfill agent used in Comparative Example 3 is carried out by using an oven for surface mount in common use.

Comparative Example 3 will be explained below with reference to the accompanying drawings.

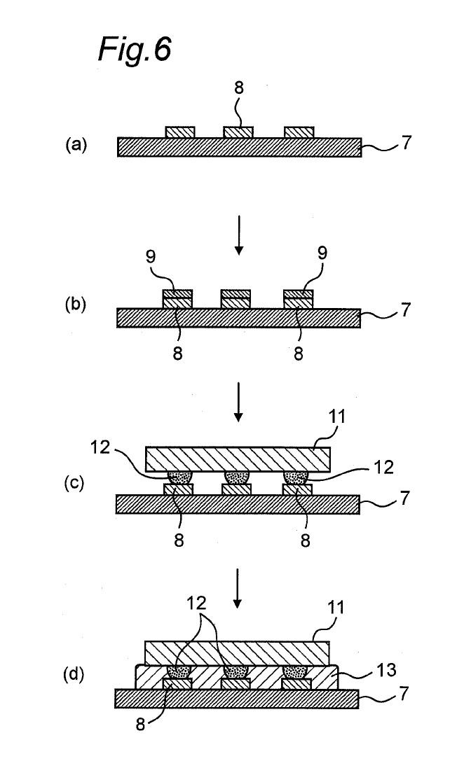

FIG. 6 is a view relating to a mounting method for bump-added electronic components in Comparative Example 3.

First, an electronic circuit board 7 was prepared (FIG. 6(a)). Next, with use of a screen printing machine, solder paste 9 of Sn-3Ag-0.5Cu was printed on electrodes 8 of the electronic circuit board 7 (FIG. 6(b)). Next, a bump-added electronic component, i.e. BGA 11, was mounted on the electronic circuit board 7 with the solder paste of Sn-3Ag-0.5Cu printed on the electrodes 8 of the electronic circuit board, and then passed through a reflow furnace, by which the bump-added electronic component, i.e. BGA 11, and the electronic circuit board 7 were joined together (FIG. 6(c)). Next, with use of a micro dispenser, an underfill agent 13 was filled between the bump-added electronic component, i.e. BGA 11, and the electronic circuit board 7 by using a capillary phenomenon, and then passed through an oven, by which a mount structure in which the underfill agent had been filled between the bump-added electronic component, i.e. BGA 11, and the electronic circuit board 7 was able to be obtained (FIG. 6(d)).

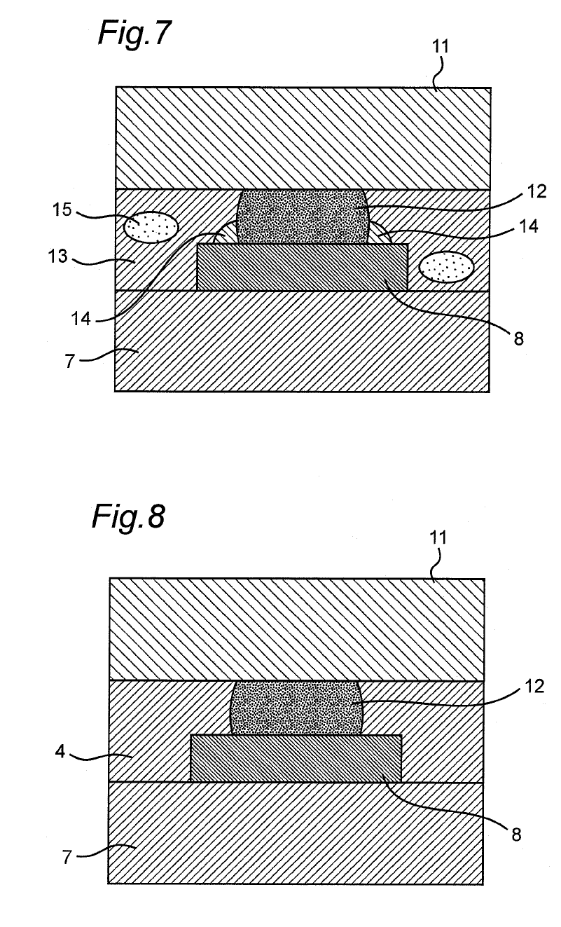

Next, a cross section of the mount structure obtained by the mounting method of Comparative Example 3 was observed. FIG. 7 shows a cross-section observation result (enlarged view) of the mount structure obtained by the mounting method of Comparative Example 3.

The cross section of the structure was observed in detail as to the state of the underfill agent 13 filled between the BGA 11 and the electronic circuit board 7 as well as to vicinities of the bump 12. As a result, two differences were observed as compared with Example 2 of the invention.

As to one of the differences, it was verified in Comparative Example 3 that flux residues 14 of the solder paste were present around the bump 12 on one side closer to the electronic circuit board 7, with peripheries of the flux residues 14 covered with the underfill agent 13. That is, it can be seen that upon penetration of the liquid-state underfill agent, the flux residues 14 had not merged into the underfill agent 13. In other words, the flux residues 14 of the solder paste and hardened materials of the underfill agent 13 were present in separation into two layers.

As to the second difference, there occurred voids 15 between the electronic circuit board 7 and the BGA 11, where it could be considered as having been filled enough with the underfill agent 13. This suggests that air present between the electronic circuit board 7 and the BGA 11, which should have been discharged out in the filling of the underfill agent 13, may fail to be discharged out due to an effect of the flux residues.

Next, a cross section (enlarged view) of the mount structure obtained by the mounting method of Example 2 was observed. FIG. 8 shows a cross-section observation result of the mount structure obtained by the mounting method of Example 2.

The cross section of the mount structure was observed in detail in terms of the state of the resin 3 having the flux action filled between the BGA 11 and the electronic circuit board 7 as well as vicinities of the bump 12. As a result, two differences were observed as compared with Comparative Example 3.

As to the first difference, in Example 2, the resin 4 having the flux action was observed in vicinities of the bump 12, while separation of the flux contained in the solder paste 9 was not observed. That is, since junction and sealing of the BGA 11 and the electrodes 8 of the electronic circuit board were processed by one-time thermal process, the resin 4 having the flux action and the flux of the solder paste were mixed together, so that the flux components were distributed uniformly in the resin 4, thus making it possible to cover the vicinities of the bump with the resin 4 having the flux action.

Herein, the wording, the flux component is “uniformly dispersed” in the resin refers to a state that the resin is not separated into multiple layers due to the types of flux components. That is, the expression refers to a state that there are no interfaces in the resin other than contact interfaces with the bumps 12, the BGA 11 or the like. As illustrated in Comparative Example 3 shown in FIG. 7, the junction between the bumps 12 and the electrodes 8 and the sealing between the BGA 11 and the electronic circuit board 7 are carried out independently of each other in Comparative Example 3. Therefore, in the junction process, the flux residues 14 stick to surfaces of the bumps 12 and the electrodes 8 as solid contents, the residues 14 being immobilized even with heat applied during the hardening of the underfill agent 13, so that the underfill agent 13 and the residues 14 are separated into two layers with the result that the interfaces are present therebetween. On the other hand, in Example 2, there are no interfaces due to such two-layer separation, making it possible to obtain a state that flux components have been dispersed uniformly in the resin 4.

As to the second difference, the resin 4 having the flux action, which was used as a sealing agent between the BGA 11 and the electronic circuit board 7, had no voids 15. This is because in the sealing of the electronic circuit board 7 and the BGA 11 using the underfill agent 13 of Comparative Example 3, the flux residues 14 of the solder blocked penetration of the underfill agent by the capillary phenomenon to block discharge of the air between the BGA 11 and the electronic circuit board 7. Furthermore, a mount structure fabricated by the method of Literatures 1 and 2 was also observed in its cross section, where voids 15 were observed. The reason of this could be considered that since the BGA 11 was mounted on the electronic circuit board 7 on which resin 4 having the flux action had been applied, air was involved in this process and, with thermal energy applied, air was not discharged outside but left as voids 15.

In the case of this invention, it is considered that since thermal energy was applied to the electrodes 8 of the electronic circuit board after the BGA 11 on which a necessary amount of resin 3 having the flux action had been applied was mounted on the solder-applied electronic circuit board 7, there did not occur voids 15 in the hardened resin 4 having the flux action.

Below described are observation and comparison of cross sections between the mount structure actually fabricated in Example 2 of the invention and the mount structure obtained by the mounting methods described in Literatures 1 and 2.

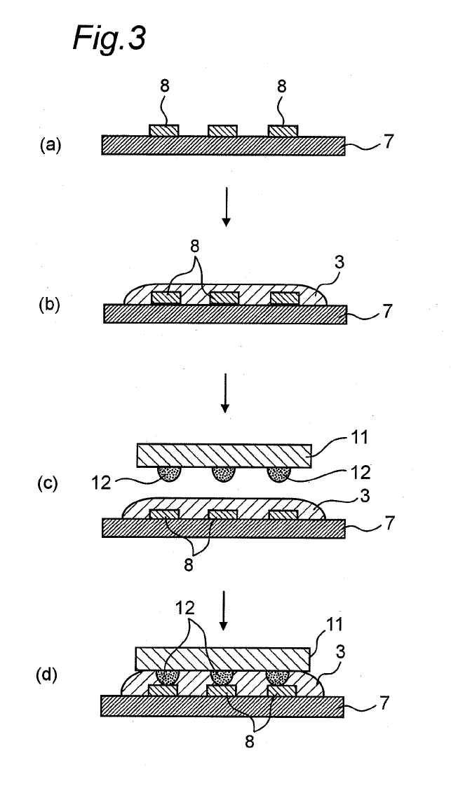

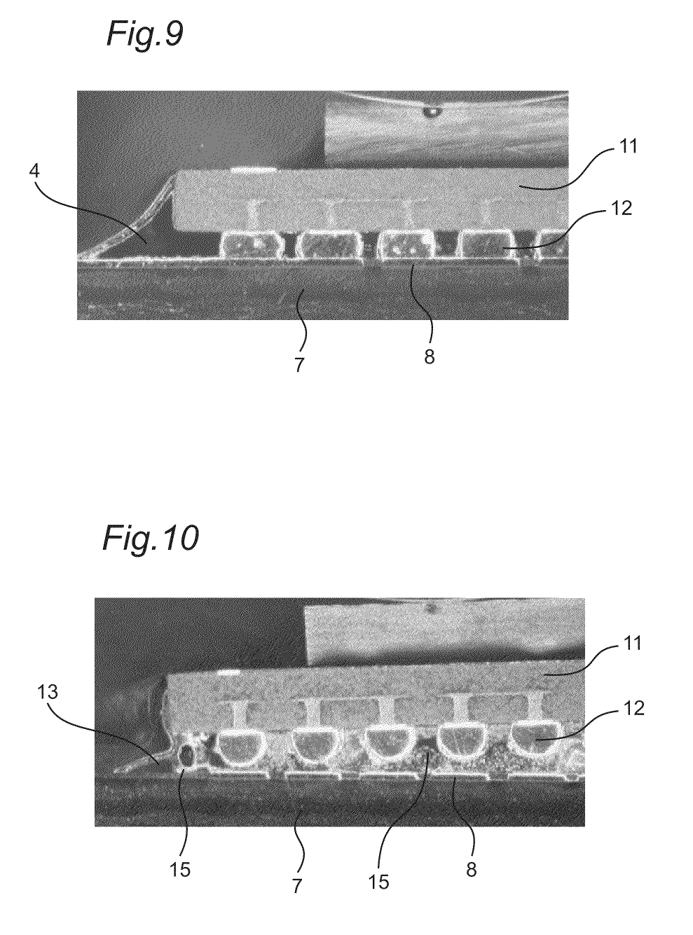

FIG. 9 shows a cross-section observation result of the mount structure obtained by the mounting method of Example 2. FIG. 10 shows a cross-section observation result of the mount structure obtained by the mounting method of Literatures 1 and 2, i.e., the structure being fabricated by the method shown in FIGS. 3(a) to 3(d). The resin 3 having the flux action, the resin 4 having the flux action and having a certain film thickness, the electronic circuit board 7, the electrodes 8 of the electronic circuit board and the bump-added electronic component (BGA 11) used in this case are the same as those of Example 2. The thickness of the resin 3 having the flux action in FIG. 3(b) was set to 150 μm as in FIG. 2(b) of Example 2.

The mount structure fabricated in Example 2 of FIG. 9 showed a secure junction between the electronic circuit board 7 and the BGA 11, as well as a filling of the resin 4 having the flux action between the electronic circuit board 7 and the BGA 11. In this case, there are no voids 15 in the hardened resin 4 having the flux action, while the resin covers entire peripheries of the bumps.

Next, by observation of the cross section of the mount structure (defective sample) obtained by the mounting method described in Literatures 1 and 2 of FIG. 10, it can be seen that there are some places where the resin 3 having the flux action was not enough filled between the electronic circuit board 7 and the BGA 11. It can also be seen that voids 15 are contained in the hardened resin 3 having the flux action.

From these results, it can be understood that the mounting method of the invention is useful in which thermal energy is applied to the electrodes 8 of the electronic circuit board after the electronic component on which a necessary amount of resin 4 having the flux action has been applied is mounted on the solder-applied electronic circuit board 7.

### Second Embodiment

As a second embodiment of the invention, below described is an example of an electronic device in which BGA-package type semiconductor devices (an example of circuit assemblies) different in size from one another are used as sub-devices, the sub-devices being provided in a multi-stage structure. Also described as a third embodiment of the invention is an example in which a plurality of sub-devices of the same size are used, the sub-devices being provided in a multi-stage structure. In addition to these, comparative examples against these embodiments, respectively, will be described as well.

In these embodiments, the sub-devices have and share individual sub-functions for fulfilling functions required as an electronic device and, when connected to one another, fulfill an aimed function as an assembly. These sub-devices may be given by using devices in which chips are mounted on a BGA-equipped multilayer printed circuit board, or by using chips having a BGA on a circuit element formation surface side, instead of the BGA-package type devices. Used as sub-devices to be placed at the lowermost layer and an intermediate layer are devices in which interconnect patterns are formed on the upper surface side parallel to the lower surface on which the BGA is provided. Used as sub-devices to be placed at the uppermost layer is a device which has the BGA on the lower surface side. Of course, a device in which interconnect patterns conforming to purposes required for the electronic device are provided on the upper surface side may also be used.

Here is described a case in which with use of sub-devices of three types of BGA packages different in size from one another, the largest-size sub-device is set at the lowermost layer, an intermediate-size sub-device is stacked thereon, and further the small-size sub-device is stacked thereon, in succession, to fabricate a targeted electronic device.

The sub-devices forming the lowermost layer and the intermediate layer, respectively, each have bumps on the lower surface side and interconnect patterns on the upper surface side. The sub-device forming the uppermost layer has bumps on the lower surface side.

For the sub-devices to form the uppermost layer and an intermediate layer, respectively, the resin having the flux action is applied on the bump-side surface up to enough specified thickness to fill clearances among the sub-devices. For the sub-devices to form an intermediate layer and the lowermost layer, respectively, solder such as solder paste is printed at their interconnect patterns, respectively. Then, the intermediate-layer sub-device is stacked on the lowermost-layer sub-device, and the uppermost-layer sub-device is stacked thereon, in succession, so that the bumps are positioned on their corresponding interconnect patterns, respectively. Thermal energy is applied to the stacked body fabricated in this way, by which the bumps and the interconnect patterns are solder joined.

The process for applying the resin having the flux action to the bump-surface side of the sub-devices may be carried out by a method in which the resin is first printed in a certain-thickness layer form and then the bump-surface side of the sub-device is put into contact with the resin layer, followed by a slight pressing or the like so that a necessary amount of the resin is transferred. This resin transfer is done in such a manner that the bumps are fully covered with the resin.

The process for applying the solder to the interconnect patterns of the sub-device is carried out by a screen printing method using a solder paste printing machine for surface mount in common use, or a dispensing method, or other like method.

As the solder, preferably used is a solder formed by adding flux to solder powder having a composition of Sn-3Ag-0.5Cu or Sn-42Bi or the like so that the solder is formed into a paste-state solder.

The process for mounting a sub-device, to which the resin having the flux action has been applied, onto another sub-device on which the solder has been applied to the interconnect patterns may be carried out by using a mounter for surface mount in common use.

The process for giving thermal energy may be carried out by using a reflow furnace of surface mount in common use.

The resin having the flux action may be provided in a liquid or paste form. A resin material to be used as a principal agent of the resin is preferably a thermosetting resin. Specific examples of the resin material include at least one kind of epoxy resin, phenol resin, polyimide resin, silicone resin as well as their modified resins and acrylic resin. Kind and blending quantity of the resin material to be used may be selected depending on bonding temperature zone, target coating film hardness and the like. A hardening agent therefor may be any one that allows the resin material in use to be hardened.

Components for developing the flux action may be an organic acid that produces reduction action, as well as a carboxylic acid or the like. Such flux components have an action of removing metal oxide coating films formed on the bumps and interconnect patterns of the sub-devices. The content rate of the flux is preferably 1-20 wt % for the resin having the flux action.

The resin having the flux action may contain a solvent, a plasticizer, a thixotropic agent or the like. The solvent, the plasticizer and the thixotropic agent are added to adjust the viscosity depending on the coating application form. The blending ratios of the solvent, the plasticizer, the thixotropic agent or the like may be set to those suited to the purpose of use.

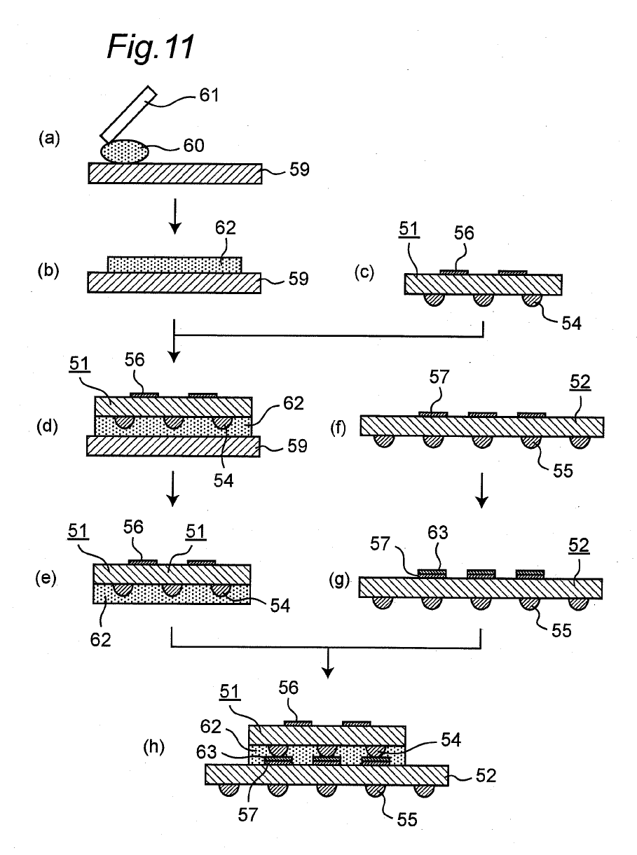

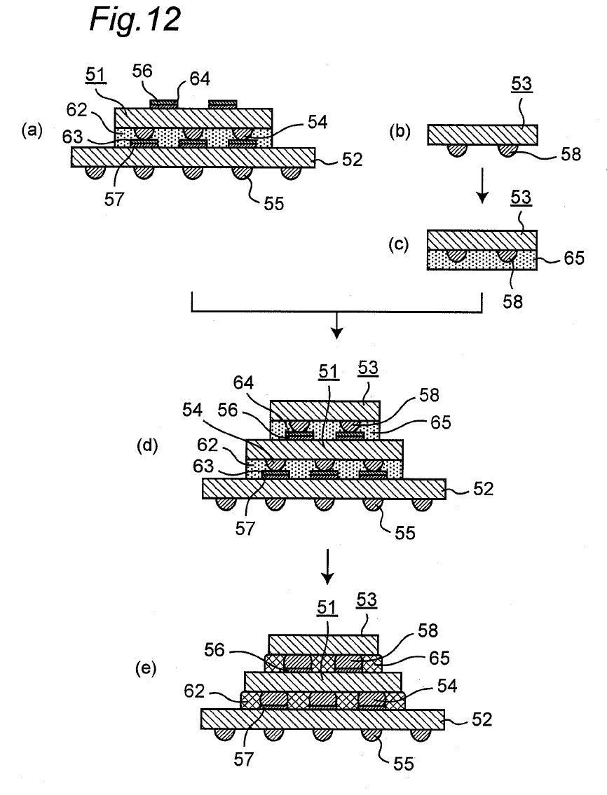

Hereinbelow, details of this second embodiment will be described with reference to FIGS. 11 and 12.

FIGS. 11 and 12 are views for explaining manufacturing processes in this second embodiment.

First, sub-devices which, when organically coupled and integrated together, fulfill functions as an electronic device are prepared. In this second embodiment, sub-devices 51, 52, 53 having three types of BGAs different in size from one another shown in FIG. 11(c), FIG. 11(f) and FIG. 12(b), respectively, are used. Out of these, the sub-device 51 shown in FIG. 11(c) is intermediate-sized to form the intermediate layer in a completed device. The sub-device 52 shown in FIG. 11(f) is larger-sized to form the lowermost layer in the completed device. Also, the sub-device 53 shown in FIG. 12(c) is smallest-sized to form the uppermost layer. In the sub-devices 51, 52, bumps 54, 55 (solder bumps) formed of solder balls are formed on their lower surface side. Also, interconnect patterns 56, 57 (electrodes) are formed on their upper surface side. The sub-device 53 forming the uppermost layer has bumps 58 on its one surface side.

The largest-sized sub-device 52 used in this case was one having the following specifications:

| | | |
|---|---|---|
| BGA circuit board dimensions: | 15.0 | mm² |
| Diameter of bump-forming ball: | 0.3 | mm |
| Bump pitch: | 0.5 | mm |
| Bump count: | 625 | pcs. |

The intermediate-sized sub-device 51 used in this case was one having the following specifications:

| | | |
|---|---|---|
| BGA circuit board dimensions: | 8.0 | mm² |
| Diameter of bump-forming ball: | 0.3 | mm |
| Bump pitch: | 0.5 | mm |
| Bump count: | 441 | pcs. |

The smallest-sized sub-device 53 used in this case was one having the following specifications:

| | | |
|---|---|---|
| BGA circuit board dimensions: | 5.0 | mm² |
| Diameter of bump-forming ball: | 0.3 | mm |
| Bump pitch: | 0.5 | mm |
| Bump count: | 121 | pcs. |

For the resin having the flux action,

A ratio of 70 wt % of bisphenol A-type epoxy resin (made by Japan Epoxy Resins Co., Ltd.) as the resin material, 15 wt % of an imidazole hardener (2P4MZ, made by Shikoku Chemicals Corporation) as the hardener, and 15 wt % of carboxylic acid (adipic acid, made by Kanto Chemical Industry Co., Ltd.) as a material for developing the flux action, were blended and kneaded by a mortar grinder. A kneading product, which was then adjusted to a viscosity of 69 Pa·s (1 rpm) by E-type viscometer, was used.

First, as shown in FIG. 11(a), a resin 60 having the flux action was thrown onto a material pot 59. Then, a squeegee 61, while kept at a specified distance to the pot 59, was moved rightward as in the figure, by which a resin layer 62 having the flux action and having a thickness of 150 μm was formed on the pot 59 (FIG. 11(b)).

Next, the sub-device 51 shown in FIG. 11(c) was pressed against the resin layer 62 held on the pot 59, and the bumps 54 were pushed into the resin layer 62 (FIG. 11(d)) and then pulled up, by which a necessary amount of resin layer 62 was transferred to the sub-device 51 (FIG. 11(e)). It is noted that the term, necessary amount of resin layer 62, refers to such an amount that the individual bumps 54 are fully covered with the resin layer 62.

Meanwhile, solder paste was selectively applied by screen printing onto the interconnect patterns 57 of the lowermost-layer sub-device 52 shown in FIG. 11(f), by which a solder layer 63 was formed (FIG. 11(g)). Then, the sub-device 51 including the resin layer 62 having the flux action was mounted on the sub-device 52 so that its bumps 54 were positioned on their corresponding interconnect patterns 57 (FIG. 11(h)). In this operation, pressing the sub-device 51 against the sub-device 52 as required makes it possible to obtain a more successful contact state of the bumps 54 and the interconnect patterns 57.

Next, solder paste was selectively printed onto the interconnect patterns 56 of the sub-device 51, by which a solder paste layer 63 was formed (FIG. 12(a)).

Meanwhile, a resin having the flux action was transferred onto a bump 58 side surface of the uppermost-layer sub-device 53 of FIG. 12(b) by the same procedure as in the foregoing case, by which a resin layer 65 was formed (FIG. 12(c)).

Then, this sub-device 53 was mounted on the sub-device 51 of the structure shown in FIG. 12(a) with positional alignment between the interconnect patterns 56 and the bumps 58 (FIG. 12(d)).

After the mounting, the sub-device assemblies 51, 52, 53 were passed through a reflow furnace for surface mount in common use, thereby being heated, so that thermal energy was given to make the solder layers 63, 64 melted. As a result, the bumps 54, 58 and the interconnect patterns 56, 57 were connected to each other, respectively, while the resin layers 62, 65 having the flux action were hardened. Thus, the sub-devices 51, 52 to each other, as well as the sub-devices 52, 53 to each other, were joined together collectively and moreover resin sealed (FIG. 12(e)).

The second embodiment has been described on a case of manufacturing an electronic device of a three-stage structure as an example. However, it is needless to say that the method of this mode can be applied to multi-stage structures of two-stage or four or more-stage structures.

### Comparative Example 4

As Comparative Example 4, an electronic device was fabricated by a method which is similar in procedure and conditions to the method of the second embodiment except that the process for forming the solder layer on the interconnect patterns 57, 56 (FIG. 11(g), FIG. 12(a)) is excluded.

### Comparative Example 5

As another comparative example, a thermosetting resin in common use was used as an underfill agent instead of the resin having the flux action. The same procedure and conditions as in the second embodiment were applied for the layer stacking of sub-devices, and after layer stacking, heating process was done to apply thermal energy for solder junction. Then, the underfill agent was filled to clearances between sub-devices, followed by heating for hardening, by which the sub-devices were resin sealed. That is, the method by Comparative Example 5 differs from the second embodiment in that an underfill agent of a different type was used, and that whereas junction between sub-devices and hardening of the underfill agent is processed by one-time heating process in the second embodiment, the those processes are carried out individually as independent processes to give thermal energy in Comparative. Example 5.

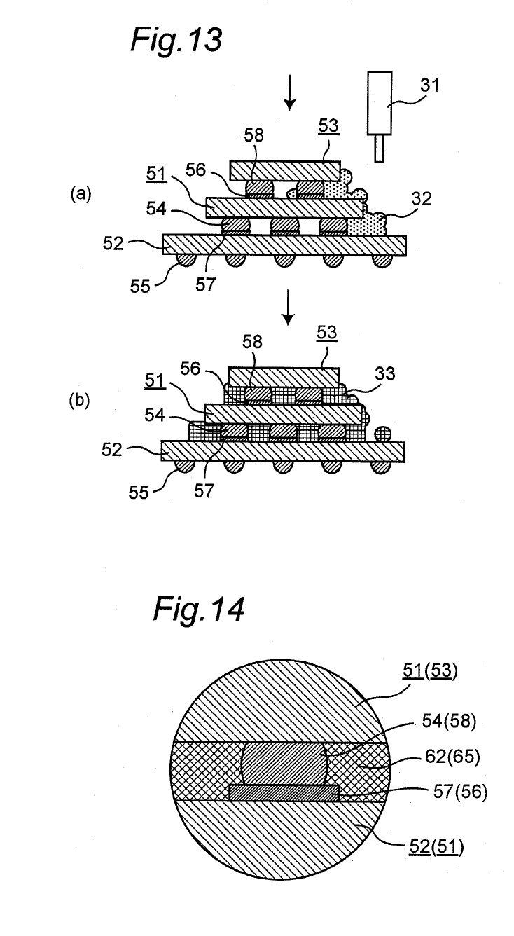

For more specific description as to the method of Comparative Example 5, after sub-devices 51, 53 were stacked in succession on the sub-device 52 as shown in FIG. 13(a), the bumps 54 and the interconnect patterns 57, as well as the bumps 58 and the interconnect patterns 56, were solder joined together, respectively. Next, onto the resulting multilayered structure, a thermosetting resin 32 was dripped by using a micro dispenser 31 so as to be penetrated into clearances between the sub-devices 51 and between the sub-devices 51 and 53. Then, the structure was passed through an oven for surface mount so as to be hardened with thermal energy given, by which a thermosetting resin layer 33 was formed so that the structure was resin sealed (FIG. 13(b)).

### Comparison Between Second Embodiment and Comparative Example 4

The electronic device obtained by the method of the second embodiment described above was cut off in its thicknesswise direction, and observed in detail in terms of its sealing state by the resin and its solder-junction state with a microscope. As a result, it was verified that the electronic device obtained by the method of the second embodiment had secure junction all between the bumps 54 and the interconnect patterns 57 and between the bumps 58 and the interconnect patterns 56, as shown by a partly enlarged view in FIG. 14. Also, the resin layers 62, 65 filled between the sub-devices 51 and 52 as well as the sub-devices 51 and 53. Then, neither voids nor residues of the flux were recognized in each of the resin layers 62, 65, and hence a very successful sealing state was verified.

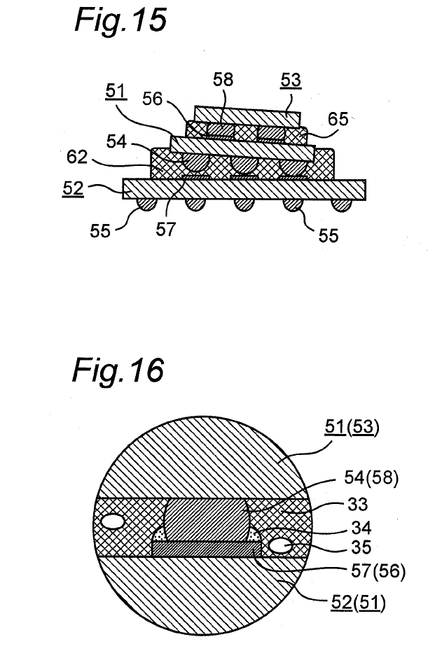

In contrast to this, in the electronic device of Comparative Example 4, it was verified that the resin having the flux action was hardened so as to be bitten between the interconnect patterns 57 and the bumps 58 as shown in FIG. 15, resulting in occurrence of junction failures. Although an example including a place where no junction was done between the sub-devices 51 and 52 is shown in this figure, there were recognized other cases in which similar junction failures due to intervention of the resin layer 65 also between the sub-devices 51, 53 occurred.

From these results, it can be considered that according to the second embodiment of the invention, the solder layer 64 and the solder layer 63 were formed on the interconnect patterns 56 and the interconnect patterns 57, respectively, so that the bumps 58, 54 and the solder layers 64, 63 were melted at the same timing of melt, thus their junction having been achieved easily and securely.

Further, even with variations in coplanarity of the interconnect-pattern surface and the bumps of the sub-devices mounted thereon, the bumps and the interconnect patterns were securely and easily joined together by adjusting the thickness of the printed layer in the printing of solder paste or the like on the interconnect patterns, so that electronic devices of arbitrary multiple-stage structure were able to be obtained.

### Comparison Between Second Embodiment and Comparative Example 5

According to the second embodiment of the invention, since a resin layer having the flux action is formed on a bump-equipped surface of a sub-devices before the sub-device is stacked, no loss of the resin material is involved, hence excellence of economy.

Meanwhile, in the method of Comparative Example 5, the underfill agent 32 is dripped to the multilayered structure of sub-devices so as to be penetrated into clearances between the sub-devices 53, 51 and between the sub-devices 51, 52 as shown in FIG. 13(a), requiring an amount of resin material more than necessary for sealing. Therefore, larger loss of material is involved, unavoidably incurring increases in manufacturing cost of the electronic device. Further, it occurs more often that the underfill agent sticks to, and remains at, places where the sticking is undesirable, causing yield declines due to appearance failures or the like.

Furthermore, the filling state of the resin layer 33 by the method of Comparative Example 5 was observed with a microscope. As a result, the following two differences were recognized in comparison to the second embodiment.

As to one of the differences, in the electronic device of Comparative Example 5, residues 34 of flux were present around the bumps 54, 58 at considerably high rates, being covered with the resin layer 33, as shown by a partly enlarged view of FIG. 16. From this result, it can be considered that as the liquid-state underfill agent 32 goes penetrating to between the sub-devices 51, 52 and between the sub-devices 53, 51, residues of the flux do not fully merge into the underfill agent 32 but at least partly remain left. That is, in the electronic device obtained by the method of Comparative Example 5, it was recognized that flux residues of the solder and hardened materials of the resin having the flux action were present in isolation from each other. In the second embodiment of the invention, the bumps 54, 58 were able to be covered with the resin layers 62, 65, respectively. The reason of this can be inferred that the junction of bumps of sub-devices and interconnect patterns and the hardening of the resin having the flux action are carried out by one identical heat treatment process, during which the flux of the solder (i.e., flux component contained in the solder paste) and the resin having the flux action (i.e., flux component contained in the resin) are mixed together so that occurrence of flux residues can be prevented.

As to the second difference, in the electronic device of Comparative Example 5, occurrence of voids 35 was recognized in the resin layers between the sub-devices 51, 52 and between the sub-devices 53, 51 formed by the filling of the underfill agent. This suggests that air between the sub-devices 51, 52 and between the sub-devices 53, 51 was not fully discharged during the filling of the underfill agent, but part of the air was left due to flux residues, so that voids were formed. That is, the reason can be considered that when the underfill agent was dripped so as to penetrate into clearances between the sub-devices 51, 52 and between the sub-devices 53, 51 by making use of the capillary phenomenon, flux residues would block not only the penetration of the underfill agent but also the discharge of the air present at the clearances.

In the second embodiment of the invention, it is considered that voids did not occur in the hardened resin layers because the resin having the flux action was used as the sealing material.

From these results, it can be understood that the method in the mode of the second embodiment is quite useful for manufacture of electronic devices having a multilayer structure.

### Third Embodiment

Next, in a third embodiment of the invention, with use of sub-devices of equal size, those sub-devices are stacked in succession by the same procedure as in the second embodiment, by which an electronic devices of a multi-stage structure is fabricated.

For the sub-devices, intermediate-sized ones described before were used. For the solder paste, a commercially available paste-state solder of Sn-3Ag-0.5Cu was used, and a solder paste printing machine for surface mount in common use was used in the process for applying the solder paste onto the interconnect patterns in a layer form. Further, for the resin material having the flux action, one obtained by blending adipic acid, which would produce reduction action, with epoxy resin and a thermosetting resin constituted of an imidazole hardener was used.

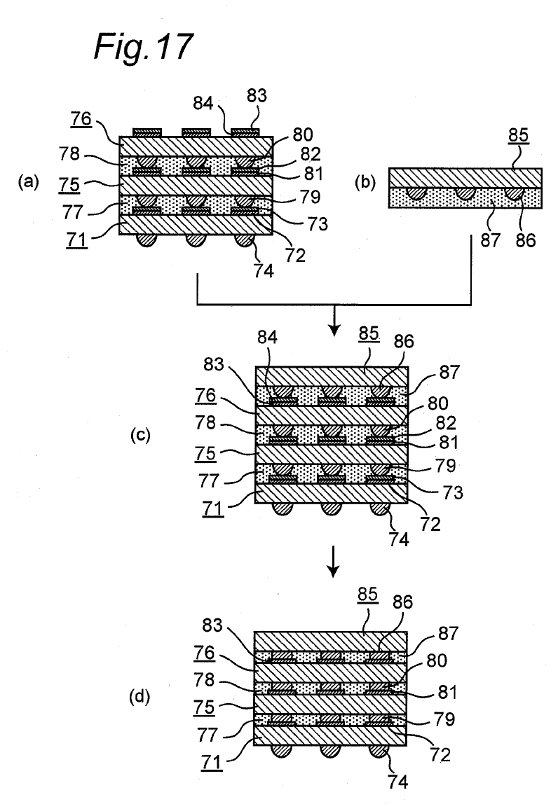

The third embodiment of the invention will be described below with reference to process views of FIG. 17.

In this third embodiment, a solder layer 73 is formed by printing solder paste to a specified thickness on interconnect patterns 72 of a sub-device 71, which forms a first layer, by screen printing process. It is noted that the sub-device 71 has bumps 74 (solder bumps) arrayed in a BGA form on one surface side other than the side on which the solder layer 73 is formed.

On sub-devices 75, 76 which are stacked as intermediate layers on the sub-device 71, resin layers 77, 78 having the flux action are formed on individual surfaces having bumps 79, 80 by the same method as the method including the processes shown in FIGS. 11(a) to 11(e). Then, while the bumps 79 are aligned with the interconnect patterns 72 and pressed against the first-layer sub-device 71 at a specified pressing force, the sub-device 75, which forms a solder layer, is stacked on the sub-device 71. Then, a solder paste layer 82 is formed on interconnect patterns 81 of the sub-device 75. Thereafter a sub-device 76, which forms a third layer, is stacked on the sub-device 75 by the same procedure, and a solder paste layer 84 is formed on interconnect patterns 83 of the sub-device 76 (FIG. 17(a)).

Also for a sub-device 85, which forms a fourth layer shown in FIG. 17(b) that is the uppermost layer, a resin layer 87 having the flux action is formed on a bump 86 side surface of the sub-device 85 in the same way (FIG. 17(b)), and the resin layer 87 is stacked on the third-layer sub-device 76 (FIG. 17(c)).

Then, the stack structure is passed through a reflow furnace so as to be subjected to heat treatment, by which junction between interconnect patterns and bumps of neighboring sub-devices as well as sealing by hardening of the resin having the flux action, are concurrently carried out (FIG. 17(d)).

A case in which an electronic device of a four-stage structure has been described above. However, for electronic devices of more stages, the above-described procedure may be repeated so that electronic devices of desired numbers of stages can easily be fabricated. Of course, electronic devices of two- or three-stage structure can easily be manufactured in a similar manner.

As described above, according to this third embodiment, even in the case where sub-devices of equal size are used, clearances between those sub-devices can be resin-sealed reliably and easily without causing occurrence of voids. Besides, there is no fear that part of the flux is left as residues in the resin layers.

### Comparative Example 6

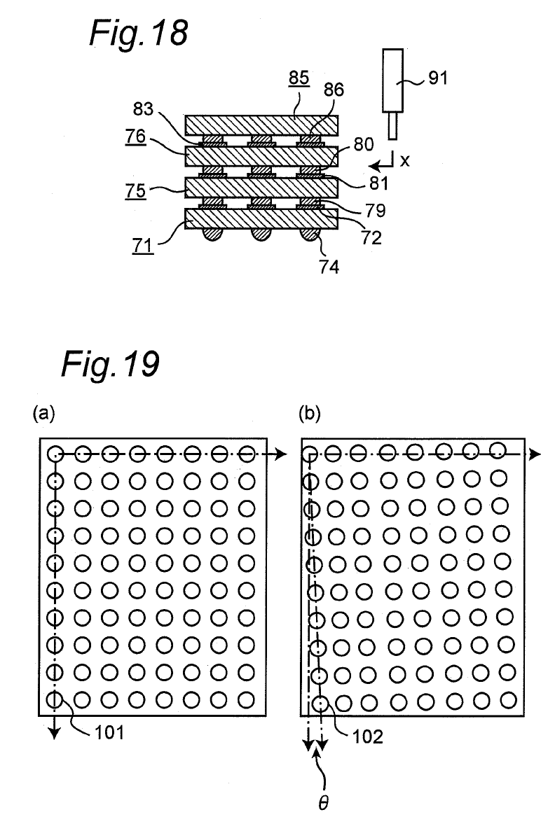

For comparison's sake, sub-devices 71, 75, 76, 85 were layer-stacked in the same procedure as in the third embodiment without using a resin having the flux action. Then, an attempt was made to fill the underfill agent to clearances between neighboring sub-devices with use of a micro dispenser 91 for surface mount as shown in FIG. 18.

However, with this method, it was impossible to fill the underfill agent over entire regions between the sub-devices due to the reason that the neighboring sub-devices were of the same size.

### Comparative Example 7

Further, for comparison's sake, an electronic device was fabricated by the same conditions and procedure as in the third embodiment except that the process for transferring and forming resin layers having the flux action on sub-devices was excluded.

This electronic device by Comparative Example 7 and the electronic device fabricated by the method of the third embodiment of the invention were examined for the state of their junction portions, respectively, by X-ray transmission.

As a result, with the device of the third embodiment, it was verified that junction was achieved as bumps 101 were aligned with the interconnect patterns as shown in FIG. 19(a) without any positional shifts.

In contrast to this, according to Comparative Example 7, 0.1 to 0.2 mm positional shifts of bumps 102 to interconnect patterns were recognized as shown in FIG. 19(b). In addition, FIG. 19(b) shows an example in which bump arrays were shifted by an angle θ in a rotational direction with respect to a reference line.

The reason that such results were obtained can be considered as follows.

According to the second embodiment of the invention, before thermal energy is given to melt the solder layer on the interconnect patterns in the heating process, the resin having the flux action is gelated by a hardener contained in the resin so that the resin is given viscosity. By this viscosity of the resin, the multi-stage structure of the sub-devices is retained and occurrence of positional shifts of the solder junction portions is prevented or suppressed. Then, while the viscosity of the resin is maintained, the solder printed on the interconnect patterns is melted so that the bumps are partly or entirely melted, by which junction of the interconnect patterns and the bumps between the sub-devices is achieved. As a result, occurrence of such phenomena as junction failure and non-junction due to positional shifts between the sub-devices can be prevented.

Thus, according to this embodiment of the invention, in order to obtain an electronic device having a multi-stage structure, solder junction between sub-devices as well as filling of the resin between the sub-devices to cover BGA-forming bumps with the resin without clearances can be achieved by one-time heat treatment, so that an electronic device of high function and high reliability can be fabricated.

For the individual embodiments of the invention, it is preferable that the resin having the flux action contain at least two or more kinds of flux components (flux components for solder bumps; e.g., organic acid) having different melting points. As a concrete example, a resin containing two kinds of flux components, glutaric acid (melting point: 97° C.) and diglycollic acid (melting point: 141-145° C.), is used. Solder paste generally contains flux components (for solder paste); for example, rosin A (softening point: 80-87° C.), rosin B (softening point: 80-90° C.), rosin C (softening point: 84-94° C.) and rosin D (softening point: 122-134° C.) are used in mixture. Preferably, the flux components are used in such a way that the range (80-134° C.) of softening point of flux components for solder paste, and the range (97-141° C.) of melting point of flux components for bumps, have mutually overlapped temperature ranges. In this case, flux components contained in the solder paste and the flux components for bumps contained in the resin exert action in the same temperature zone under the same temperature profile of reflow, so that the removal effect of metal oxide films can be enhanced in such a temperature zone, making it possible to achieve a successful junction state between the solder paste and the bumps. Also, in the resin manufactured with use of such flux components, flux components contained in the solder paste and flux components for bumps originally contained in the resin are uniformly mixed together and dispersed in the resin by convection of the heated resin.

In addition, for example, adipic acid is used as the flux component when the electronic component is a chip component or the like, and diglycollic acid and glutaric acid are used as the flux components when the electronic component is a BGA or the like.

According to the electronic device manufacturing method (i.e., mounting method) of the invention, the solder layer is formed on the interconnect patterns of a lower-layer sub-device before an upper-layer sub-device is set in place. Therefore, even if the lower-layer sub-device is warped in a thermal-energy applying process of the constitution in use, the warp amount can be absorbed by adjustment of the thickness of the solder layer. This makes it possible to connect sub-devices to each other even if the sub-devices are warped. In addition to this, even if metal balls formed of bump-forming solder or the like are varied in size, effects due to the size variations can easily be solved by correspondingly adjusting the thickness of the solder layer.

Also, resin layers having the flux action are formed on bump-side surfaces of upper-layer sub-devices, respectively, by which a multi-stage structure is layer-stacked. Therefore, before melting of the solder layer applied and formed on the interconnect patterns during application of thermal energy, the resin layers between the sub-devices are gelated. As a result, the resin is given viscosity, and the viscosity allows the multi-stage structure of the sub-devices to be retained, so that occurrence of positional shifts between the sub-devices at their solder junction portions can be prevented.

Further, since a resin having the flux action is used as the resin for filling clearances between the sub-devices, metal oxide coating films formed on the bump surfaces of the sub-devices can be removed by the resin during application of thermal energy. In particular, since the resin is set so as to entirely cover the individual bumps, the metal oxide coating films can be removed from all over the surfaces of the bumps covered with the resin. Accordingly, the bumps can be melted in a successful state, so that a successful electroconductivity with the solder layers formed on the interconnect patterns can be obtained.

As shown above, effects of the warp or the positional shifts are substantially solved, and moreover it is made possible to remove metal oxide coating films on the bump surfaces that would obstruct the connection between the bumps and the interconnect patterns during sealing process. Thus, the reliability of connection between the sub-devices can be improved.

Further, according to the method of the invention, the resin for sealing of the sub-devices is enabled to exert the flux action, and the resin is applied in enough amount to sufficiently fill clearances between the sub-devices. As a result, not only it becomes possible to cover the connecting portions between bumps and interconnect patterns, but also occurrence of residues, such as when flux alone is used, can be blocked.

Accordingly, sub-devices can be sealed from one another with the resin without causing occurrence of flux residues or voids, so that the reliability of sealing can be improved.

Furthermore, according to the method of the invention, since the connection between sub-devices and their sealing can be achieved in one common thermal-energy applying process, it becomes possible to reduce the number of manufacturing processes, simplification of equipment used, and the like. As a result, electronic devices of multi-stage structures can be manufactured with remarkable simplicity and with low cost.

It is to be noted that, by properly combining the arbitrary embodiments of the aforementioned various embodiments, the effects possessed by them can be produced.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

The entire disclosure of Japanese Patent Application No. 2008-275108 filed on Oct. 27, 2008, including specification, claims, and drawings as well as the entire disclosure of Japanese Patent Application No. 2009-028818 filed on Feb. 10, 2009, including specification, claims, and drawings are incorporated herein by reference in its entirety.

What is claimed is:

1. An electronic device comprising:
a first circuit assembly having electrodes;
a second circuit assembly which is set opposite to an electrode formation surface of the first circuit assembly and which has solder bumps electrically connected to the electrodes, respectively; and
a resin which is set between the first circuit assembly and the second circuit assembly to join together the first circuit assembly and the second circuit assembly and which seals the electrodes and the solder bumps connected to each other, respectively, wherein
at least two or more kinds of flux components including a flux component for solder bumps are mixed up so as to be dispersed in the resin.

2. The electronic device as defined in claim 1, wherein the second circuit assembly has electrodes formed on a surface opposed to a bump formation surface of the second circuit assembly, the electronic device further comprising:
a third circuit assembly which is set opposite to an electrode formation surface of the second circuit assembly and which has solder bumps electrically connected to the electrodes, respectively; and
a resin which is set between the second circuit assembly and the third circuit assembly to join together the second circuit assembly and the third circuit assembly and which seals the electrodes and the solder bumps connected to each other, respectively.

3. The electronic device as defined in claim 1, wherein two or more kinds of organic acids having different melting points are contained as flux components in the resin.

4. The electronic device as defined in claim 3, wherein a melting point range of one flux component contained in the resin and a melting point range of another flux component contained in the resin have a mutually overlapped temperature range.

5. The electronic device as defined in claim 3, wherein as the two or more kinds of organic acids having different melting points, diglycollic acid and glutaric acid are contained in the resin.

6. The electronic device as defined in claim 1, wherein flux components within a quantity range of 1 to 20 wt % are contained and dispersed in the resin.

7. An electronic device manufacturing method comprising:
setting a solder material on electrodes of a first circuit assembly;
setting a resin having a flux action on one surface of a second circuit assembly so as to entirely cover solder bumps formed on the one surface of the second circuit assembly;
setting the second circuit assembly on the first circuit assembly via the resin so that the solder material set on the electrodes of the first circuit assembly and the solder bumps of the second circuit assembly are put into contact with each other; and
applying thermal energy to connecting portions between the solder material and the solder bumps and to the resin, whereby
an electronic device in which the first circuit assembly and the second circuit assembly are joined together and in which their junction portions are sealed by the resin is manufactured.

8. The electronic device manufacturing method as defined in claim 7, wherein
in the thermal energy applying process, the thermal energy is applied to junction portions and the resin without exerting pressure between the first circuit assembly and the second circuit assembly.

9. The electronic device manufacturing method as defined in claim 7, wherein
in the thermal energy applying process, the thermal energy is applied to the resin having the flux action, whereby oxide films on surfaces of the solder bumps are removed so that the solder bumps are electrically connected to the electrodes of the first circuit assembly.

10. The electronic device manufacturing method as defined in claim 7, wherein
in the thermal energy applying process, the thermal energy is applied to the resin having the flux action, whereby the resin is hardened.

11. The electronic device manufacturing method as defined in claim 7, wherein
in the process of setting the resin having the flux action on one surface of the second circuit assembly, the one surface of the second circuit assembly is brought into contact with a resin layer formed to a thickness higher larger than a height of the solder bumps, whereby the resin layer is transferred onto the second circuit assembly.

12. The electronic device manufacturing method as defined in claim 7, further comprising:
setting the solder material onto electrodes formed on the other surface of the second circuit assembly;
setting the resin having the flux action onto one surface of a third circuit assembly so as to entirely cover solder bumps formed on the one surface of the second circuit assembly; and
setting the third circuit assembly onto the second circuit assembly via the resin so that the solder material set on the electrodes of the second circuit assembly and the solder bumps of the third circuit assembly are put into contact with each other, whereby
in the thermal energy applying process, the thermal energy is applied to connecting portions of the solder material and the solder bumps between the first circuit assembly, the second circuit assembly and the third circuit assembly, so that the first circuit assembly, the second circuit assembly and the third circuit assembly are joined together and moreover their individual connecting portions are sealed by the resin, whereby an electronic device is manufactured.

13. The electronic device manufacturing method as defined in claim 7, wherein the solder bumps formed on the second circuit assembly have a BGA structure.

14. The electronic device manufacturing method as defined in claim 7, wherein
in the process of setting the resin having the flux action onto one surface of the second circuit assembly, a resin containing a principal ingredient of a resin material, a hardener of the principal ingredient, and an organic acid having the flux action are set onto the one surface of the second circuit assembly.

15. The electronic device manufacturing method as defined in claim 14, wherein at least two or more kinds of organic acids having different melting points are contained as the resin having the flux action.

16. The electronic device manufacturing method as defined in claim 15, wherein
the solder material set on the electrodes of the first circuit assembly contains a flux component, and
a softening point range of the flux component of the solder material and a melting point range of the two or more kinds of organic acids contained in the resin has a mutually overlapping temperature range.

17. The electronic device manufacturing method as defined in claim 15, wherein as the two or more kinds of organic acids having different melting points, diglycollic acid and glutaric acid are contained in the resin.

18. The electronic device manufacturing method as defined in claim 7, wherein flux components within a quantity range of 1 to 20 wt % are contained in the resin.

19. An electronic device manufacturing method comprising:
setting a solder material on a board electrode of a circuit board;
setting a resin having a flux action on an electrode of a chip component;
mounting the chip component onto the circuit board via the resin so that the solder material set on the board electrode of the circuit board and the electrode of the chip component are put into contact with each other; and
applying thermal energy to the solder material and the resin, wherein
an electronic device in which the electrode of the chip component is electrically connected to the board electrode of the circuit board via the solder material and in which their connecting portions are sealed by the resin is manufactured.
